(19) United States
(12) Patent Application Publication
(10) Pub. No.: US 2011/0027726 A1
(43) Pub. Date: Feb. 3, 2011

(54) POLYMER COMPOUND FOR PHOTORESIST

(76) Inventors: Kiyoharu Tsutsumi, Hyogo (JP); Arimichi Okumura, Hyogo (JP)

Correspondence Address: BIRCH STEWART KOLASCH & BIRCH, PO BOX 747, FALLS CHURCH, VA, 22040-0747, US

(21) Appl. No.: 12/935,848

(22) PCT Filed: Apr. 2, 2009
(86) PCT No.: PCT/JP2009/001558

§ 371 Date: Sep. 30, 2010

(30) Foreign Application Priority Data
Apr. 4, 2008 (JP) 2008-098508

(51) Int. Cl. G03F 7/20; C08G 75/24

(52) U.S. Cl. 430/325; 528/173

(57) ABSTRACT

A polymer compound for photoresists contains alkali-soluble groups being protected by protecting groups capable of leaving with an acid, and is thereby insoluble or sparingly soluble in an alkaline developer, in which part or all of the protecting groups are multifunctional protecting groups each protecting two or more alkali-soluble groups. The alkali-soluble groups may be phenolic hydroxyl groups. The polymer compound may correspond to a polyol compound having an aliphatic group and an aromatic group bound to each other alternately, the aromatic group having an aromatic ring and two or more hydroxyl groups bound to the aromatic ring, except with phenolic hydroxyl groups of the polyol compound being protected by protecting groups capable of leaving with an acid.

The polymer compound for photoresists can give a resist film with less line edge roughness (LER), while exhibiting excellent workability and resolution.

### TECHNICAL FIELD

The present invention relates to a polymer compound for photoresists, in which two or more alkali-soluble groups are protected by a protecting group capable of leaving with an acid (eliminating by the action of an acid). The present invention also relates to a photoresist composition containing the polymer compound for photoresists, and to a process for the formation of a resist pattern using the photoresist composition.

### BACKGROUND ART

Recent improvements in lithographic technologies rapidly move patterning for the production of semiconductor devices and liquid crystal displays to finer design rules. Such patterning in finer design rules has been generally achieved by adopting light sources having shorter wavelengths. Specifically, ultraviolet rays represented by g line (g ray) and i line (i ray) were customarily used, but commercial production of semiconductor devices using KrF excimer laser and ArF excimer laser has been launched. Further recently, lithography processes using extreme ultraviolet (EUV; having a wavelength of about 13.5 nm) and those using electron beams have been proposed as next-generation technologies succeeding to the lithography process using ArF excimer laser (193 nm).

Chemically-amplified resists are known as one of resist materials which have such high resolutions as to reproduce patterns with fine dimensions. The chemically-amplified resists each contain a base component capable of forming a film and capable of becoming soluble in an alkali by the action of an acid; and an acid generator component capable of generating an acid upon irradiation with light (upon exposure).

Such resist materials, when used for the formation of patterns, cause roughness of the top surface and sidewall surface of the patterns. The roughness was trivial in the past but has recently become a serious problem, because further higher resolutions are demanded in production typically of semiconductor devices in finer design rules. For example, when a line pattern is formed, the roughness of the sidewall surface of the pattern, i.e., line edge roughness (LER) causes a variation in line width. The variation in line width is desirably controlled to be about 10% or less of the ideal width, but LER more affects the variation in line width with decreasing pattern dimensions. However, customarily used polymers are difficult to give resist patterns with less LER, because they have a large average particle diameter of about several nanometers per one molecule.

An exemplary candidate for the reduction of LER by adopting a polymer having a small average particle diameter per one molecule is a resist composition described in Patent Document 1. This resist composition contains a polyhydric phenol compound, and an acid generator component capable of generating an acid upon exposure. This resist composition, however, readily undergoes crystallization due to the small molecular weight of the polymer, and application (coating) thereof typically to a base (substrate) tends to be difficult, resulting in inferior workability. In addition, a polymer having such a small molecular weight often causes pattern collapse, resulting in a problem of lower resolution. Specifically, under present circumstances, there has been found no resist composition which can give a resist pattern with less LER while exhibiting excellent workability and resolution.

### Citation List

### Patent Document

Patent Document 1: Japanese Unexamined Patent Application Publication (JP-A) No. 2006-78744

### SUMMARY OF INVENTION

### Technical Problem

Accordingly, an object of the present invention is to provide a polymer compound for photoresists, which can give a resist pattern with less LER while exhibiting excellent workability and resolution.

Another object of the present invention is to provide a photoresist composition containing the polymer compound for photoresists; and a process for the formation of a resist pattern using the photoresist composition.

### Means far Solving the Problems

After intensive investigations to achieve the objects, the present inventors have found a polymer compound for photoresists structurally having two or more molecules of an alkali-soluble polymer compound bound to each other through a protecting group capable of leaving with an acid. They have found that, in the absence of the action of an acid, the polymer compound for photoresists has a large molecular weight and is resistant to crystallization even when a constitutional alkali-soluble polymer compound has a small molecular weight, because the polymer compound contains two or more molecules of the alkali-soluble polymer compound bound to each other through the protecting group; and that the polymer compound for photoresists gives a resist film with less pattern collapse while showing excellent workability. They also have found that LER can be reduced because the binding between molecules of the alkali-soluble polymer compound can be easily dissociated by allowing an acid to act to allow the protecting group to leave (eliminate). The present invention has been made based on these findings and further investigations.

Specifically, the present invention provides, in an embodiment, a polymer compound for photoresists. This polymer compound contains alkali-soluble groups being protected by protecting groups capable of leaving with an acid, and is insoluble or sparingly soluble in an alkaline developer, in which part or all of the protecting groups are multifunctional protecting groups each protecting two or more alkali-soluble groups.

The alkali-soluble groups in the polymer compound for photoresists are preferably phenolic hydroxyl groups. The polymer compound for photoresists are preferably a polyol compound having at least one aliphatic group and at least one aromatic group bound to each other alternately, the aromatic group having at least one aromatic ring and two or more phenolic hydroxyl groups bound to the aromatic ring. The phenolic hydroxyl groups in the polyol compound are preferably a group protected by protecting groups capable of leaving with an acid.

The polyol compound is preferably a product of an acid-catalyzed reaction between an aliphatic polyol and an aromatic polyol. The acid-catalyzed reaction is more preferably a Friedel-Crafts reaction.

The aliphatic polyol is preferably an alicyclic polyol, of which an adamantanepolyol having an adamantane ring and two or more hydroxyl groups bound at the tertiary positions of the adamantane ring is more preferred.

The aromatic polyol is preferably hydroquinone or a naphthalenepolyol.

The polymer compound for photoresists before the protection of alkali-soluble groups by protecting groups capable of leaving with an acid (hereinafter this polymer compound is also referred to as an “alkali-soluble polymer compound”) preferably has a weight-average molecular weight of 500 to 5000.

Preferably, an acetal structure is formed through the protection of the alkali-soluble group by the protecting group capable of leaving with an acid; and the acetal structure is preferably formed through a reaction between a phenolic hydroxyl group and a vinyl ether compound.

The present invention provides, in another embodiment, a photoresist composition containing at least the polymer compound for photoresists.

In yet another embodiment, the present invention provides a process for the formation of a resist pattern. The process includes the steps of forming a resist film from the photoresist composition; pattern-wise exposing the resist film; and developing the pattern-wise-exposed resist film.

### Advantages

In the polymer compound for photoresists according to the present invention, a protecting group capable of leaving with an acid protects two or more alkali-soluble groups. In the absence of the action of an acid to the polymer compound for photoresists, two or more molecules of an alkali-soluble polymer compound are bound to each other through the protecting group, the polymer compound for photoresists thereby has a large molecular weight, is resistant to crystallization, excels in workability, and gives a resist film with less pattern collapse. In contrast, in the presence of the action of an acid to the polymer compound for photoresists, the action causes to leave the protecting group and to dissociate the binding between the molecules of the alkali-soluble polymer compound, and then the polymer compound for photoresists can give a resist pattern with less LER. For example, even in photolithography using extreme ultraviolet (EUV; having a wavelength of about 13.5 nm) so as to give a line-and-space pattern of about 22 nm, the polymer compound for photoresists can give a high-resolution resist pattern with a reduced LER of 2 nm or less.

### Description of Embodiments

[Polymer Compounds for Photoresists]

Polymer compounds for photoresists according to the present invention are polymer compounds for photoresists which contain alkali-soluble groups being protected by protecting groups capable of leaving with an acid and which are thereby insoluble or sparingly soluble in an alkaline developer, in which part or all of the protecting groups are multifunctional protecting groups each protecting two or more alkali-soluble groups.

Exemplary alkali-soluble groups include phenolic hydroxyl groups, carboxyl groups, sulfo groups, and hexafluoroisopropanol groups. Among them, phenolic hydroxyl groups excel in etching resistance, show moderate acidity, and are thereby preferred in the present invention.

Exemplary structures formed by the protection of alkali-soluble group by the protecting group capable of leaving with an acid include tertiary ester, formal, acetal, ketal, and carbonate structures. Among them, an acetal structure is preferred in the present invention as the structure formed through the protection of alkali-soluble group by the protecting group capable of leaving with an acid, because the resulting polymer compound having such acetal structure shows a higher sensitivity.

In the polymer compounds for photoresists according to the present invention, part or all of the protecting groups are multifunctional protecting groups, and preferably, part or all of the protecting groups each have two or more acetal structures.

If all the alkali-soluble groups in a polymer compound for photoresists are protected by the protecting groups, the entire polymer compound for photoresists becomes hydrophobic and tends to have insufficient adhesion property with respect to a base (substrate) and insufficient wettability with an alkaline developer. To avoid these, it is desirable to control the rate of protected alkali-soluble groups at a predetermined level or to use a protecting group having a polar functional group. Examples of the polar functional groups include, but are not limited to, ether bond, ketone bond, and ester bond.

The protecting group preferably has an electron-withdrawing group, such as carbonyl group, trifluoromethyl group, or cyano group. The protecting group, when having an electron-withdrawing group, shows moderately controlled capability of leaving with an acid (leaving activity) and helps the polymer compound for photoresists to have improved storage stability.

The acetal structure can be formed according to a variety of techniques without limitation, such as a technique of reacting a phenolic hydroxyl group or groups with a 1-halogenated ethyl ether compound; or a technique of reacting a phenolic hydroxyl group or groups with a vinyl ether compound. The technique of reacting a phenolic hydroxyl group or groups with a vinyl ether compound is preferably adopted in the present invention, because there are a wide variety of vinyl ether compounds usable in the technique.

It is preferred to use at least one of multivalent vinyl ether compounds each having two or more vinyl groups (e.g., divinyl ether compounds, trivinyl ether compounds, tetravinyl ether compounds, and hexavinyl ether compounds) as the vinyl ether compound. Each of these multivalent vinyl ether compounds can be used alone or in combination. It is also acceptable to use one or more monovinyl ether compounds in combination with one or more multivalent vinyl ether compounds. In a preferred embodiment of the present invention, one or more divinyl ether compounds, or a mixture of one or more divinyl ether compounds and one or more monovinyl ether compounds is used, because the resulting polymer compound for photoresists remains as liquid, thereby maintains its capability of forming a resist film, and shows excellent workability even when the alkali-soluble polymer compound has a small weight-average molecular weight, and the polymer compound for photoresists gives a resist film having improved etching resistance, and the formed resist pattern shows less pattern collapse. Such vinyl ether compounds can be synthetically prepared, for example, by reacting vinyl acetate with an alcohol in the presence of an iridium catalyst.

The vinyl ether compound is used to form protecting groups for preventing the dissolution of the polymer compound in an alkaline developer. For this purpose, nonpolar alkyl vinyl ether compounds and nonpolar aromatic vinyl ether compounds are preferably used. When the resulting photoresist composition is adopted to EUV exposure, the vinyl ether compound preferably has a molecular weight equal to or higher than a predetermined value, because contamination of apparatuses due to outgassing should be avoided in such EUV exposure, and such a vinyl ether compound having a molecular weight equal to or higher than a predetermined value less causes outgassing. Specifically, the vinyl ether compound in this use preferably has a molecular weight of about 100 to 500. A vinyl ether compound, if having an excessively small molecular weight, may tend to increase the risk of contamination of the optical system due to outgassing occurring as a result of EUV exposure. In contrast, a vinyl ether compound, if having an excessively large molecular weight, may have an excessively high viscosity and its application to a base or substrate may tend to be difficult; and the vinyl ether compound may remain as a residue on the base or substrate after development to cause post-develop defects.

Exemplary vinyl ether compounds for use in the present invention include compounds represented by following Formulae (1a) to (1m) and (2a). to (2n):

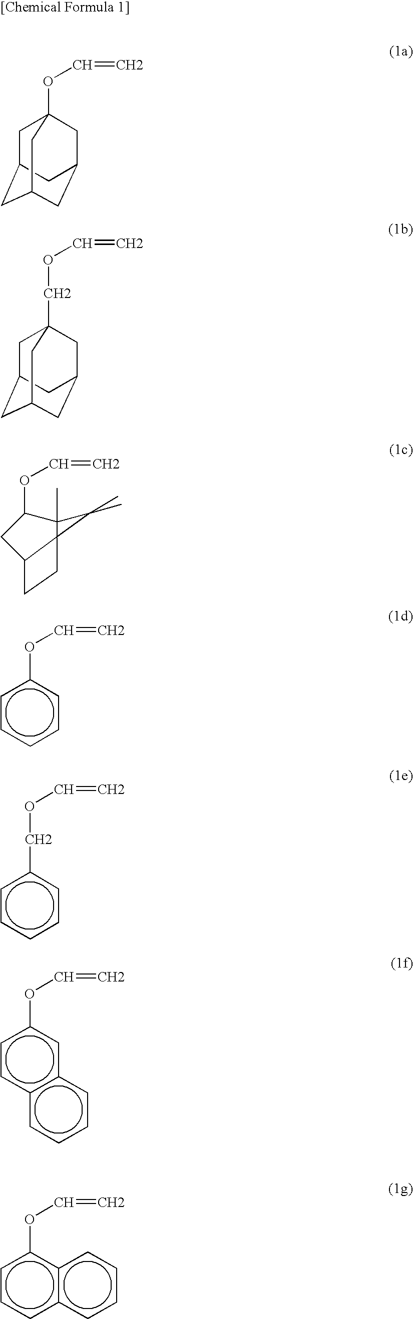

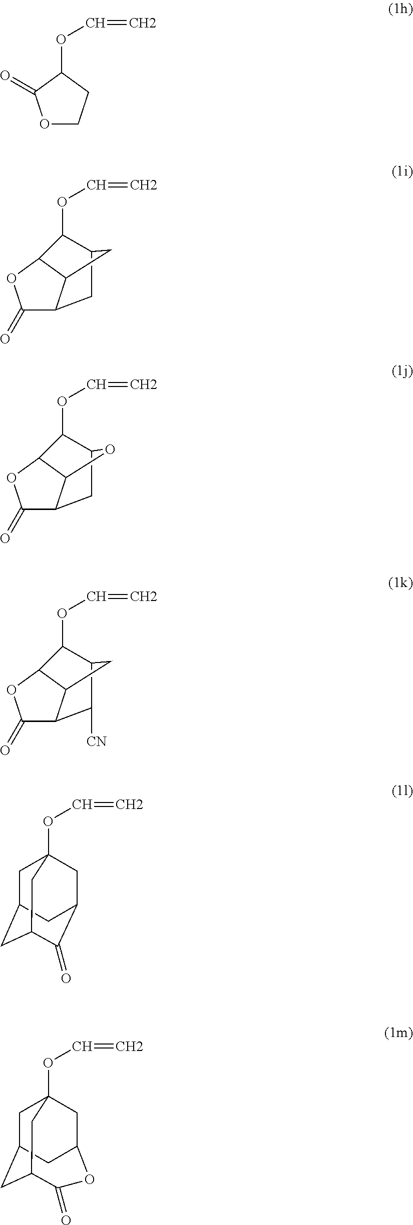

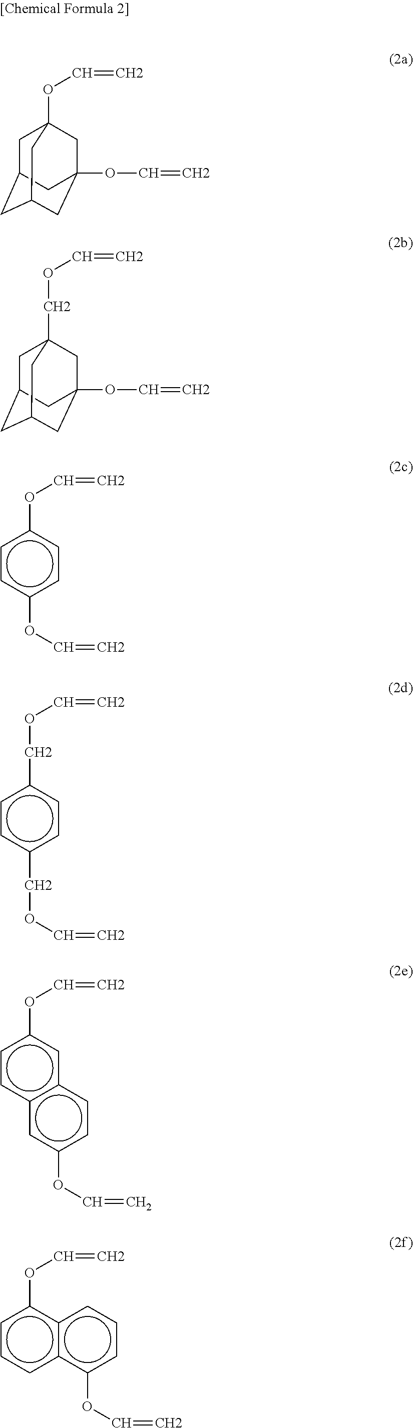

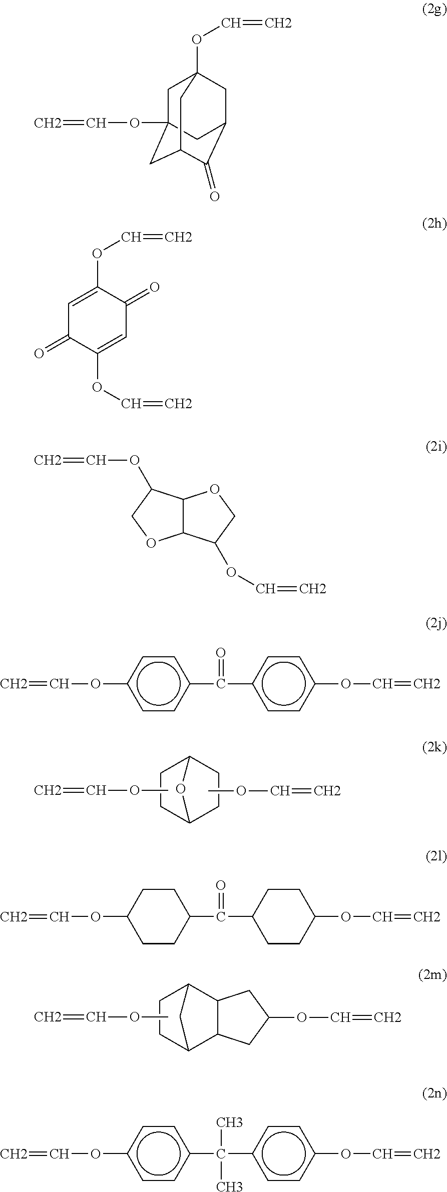

In a preferred embodiment according to the present invention, the polymer compound for photoresists are preferably a polyol compound having at least one aliphatic group and at least one aromatic group bound to each other alternately, the aromatic group having at least one aromatic ring and two or more hydroxyl groups (i.e., phenolic hydroxyl groups) bound to the aromatic ring. The phenolic hydroxyl groups in the polyol compound are preferably a group protected by protecting groups capable of leaving with an acid.

The polyol compound having at least one aliphatic group and at least one aromatic group bound to each other alternately, the aromatic group having at least one aromatic ring and two or more hydroxyl groups bound to the aromatic ring, has a structure in which at least one aliphatic group and at least one aromatic group are bound to each other alternately, which aromatic group has at least one aromatic ring and two or more hydroxyl groups bound to the aromatic ring. Examples of the polyol compound having such structure include polyol compounds each having one unit (repeating unit) composed of one aliphatic group and one aromatic group bound to each other, such as a compound having one aliphatic group and one or more aromatic groups bound thereto, and a compound having one aromatic group and two or more aliphatic groups bound thereto; polyol compounds each having two or more of the repeating unit; and mixtures of these.

The polyol compound can be produced according to a variety of processes, such as a process of subjecting an aliphatic polyol and an aromatic polyol to an acid-catalyzed reaction; a process of subjecting an aliphatic multivalent halide and an aromatic polyol to an acid-catalyzed reaction; and a process of subjecting phenol and formaldehyde to an acid-catalyzed reaction or alkali-catalyzed reaction. Among them, the process of subjecting an aliphatic polyol and an aromatic polyol to an acid-catalyzed reaction is preferably adopted in the present invention to produce the polyol compounds synthetically.

The acid-catalyzed reaction between the aliphatic polyol and the aromatic polyol is preferably a Friedel-Crafts reaction.

The aliphatic polyol compound is a compound having an aliphatic hydrocarbon group and two or more hydroxyl groups bound thereto and is represented by following Formula (3):

R—(OH)ₙ₁ (3)

wherein R represents an aliphatic hydrocarbon group; and n1 denotes an integer of 2 or more.

Examples of R in Formula (3) include chain aliphatic hydrocarbon groups, cyclic aliphatic (cycloaliphatic) hydrocarbon groups, and groups each including two or more of these bound to each other. Exemplary chain aliphatic hydrocarbon groups include alkyl groups having about 1 to 20 carbon atoms, such as methyl, ethyl, propyl, isopropyl, butyl, isobutyl, s-butyl, t-butyl, pentyl, hexyl, decyl, and dodecyl groups, of which those having about 1 to 10 carbon atoms are preferred, and those having about 1-to 3 carbon atoms are more preferred; alkenyl groups having about 2 to 20 carbon atoms, such as vinyl, allyl, and 1-butenyl groups, of which those having about 2 to 10 carbon atoms are preferred, and those having about 2 or 3 carbon atoms are more preferred; and alkynyl groups having about 2 to 20 carbon atoms, such as ethynyl and propynyl groups, of which those having about 2 to 10 carbon atoms are preferred, and those having about 2 or 3 carbon atoms are more preferred.

Exemplary cycloaliphatic hydrocarbon groups include cycloalkyl groups having about 3 to 20 members, such as cyclopropyl, cyclobutyl, cyclopentyl, cyclohexyl, and cyclooctyl groups, of which those having about 3 to 15 members are preferred, and those having about 5 to 8 members are more preferred; cycloalkenyl groups having about 3 to 20 members, such as cyclopentenyl and cyclohexenyl groups, of which those having about 3 to 15 members are preferred, and those having about 5 to 8 members are more preferred; and bridged hydrocarbon groups such as perhydronaphth-1-yl group, norbornyl, adamantyl, and tetracyclo[4.4.0.1^{2,5}. 1^{7,10}]dodec-3-yl groups.

Exemplary hydrocarbon groups each having a chain aliphatic hydrocarbon group and a cycloaliphatic hydrocarbon group bound to each other include cycloalkyl-alkyl groups such as cyclopentylmethyl, cyclohexylmethyl, and 2-cyclohexylethyl groups, of which cycloalkyl-alkyl groups whose cycloalkyl moiety having 3 to 20 carbon atoms and whose alkyl moiety having 1 to 4 carbon atoms are preferred.

The hydrocarbon groups may each have one or more substituents, such as halogen atoms, oxo group, hydroxyl group, substituted oxy groups (e.g., alkoxy groups, aryloxy groups, aralkyloxy groups, and acyloxy groups), carboxyl group, substituted oxycarbonyl groups (e.g., alkoxycarbonyl groups, aryloxycarbonyl groups, and aralkyloxycarbonyl groups), substituted or unsubstituted carbamoyl groups, cyano group, nitro group, substituted or unsubstituted amino groups, sulfo group, and heterocyclic groups. The hydroxyl group and carboxyl group may be respectively protected by protecting groups customarily used in organic syntheses.

The aliphatic polyol for use in the present invention is preferably an alicyclic polyol, for further higher etching resistance. The alicyclic polyol is a compound having an alicyclic skeleton, and the hydroxyl groups may be bound to the alicyclic skeleton directly or indirectly through linkage groups. Exemplary linkage groups include alkylene groups (e.g., alkylene groups having 1 to 6 carbon atoms); and groups each including one or more of the alkylene groups and at least one group selected from the group consisting of —O—, —C(═O)—, —NH—, and —S— bound to each other.

Examples of the alicyclic polyol include alicyclic polyols such as cyclohexanediol, cyclohexanetriol, cyclohexanedimethanol, isopropylidenedicyclohexanol, decahydronaphthalenediol(decalindiol), and tricyclodecanedimethanol; and bridged alicyclic polyols of Formula (3) in which R is a ring selected from the group consisting of rings represented by following Formulae (4a) to (4j) or R is a ring including two or more of these rings bound to each other, in which two or more hydroxyl groups are bound to R.

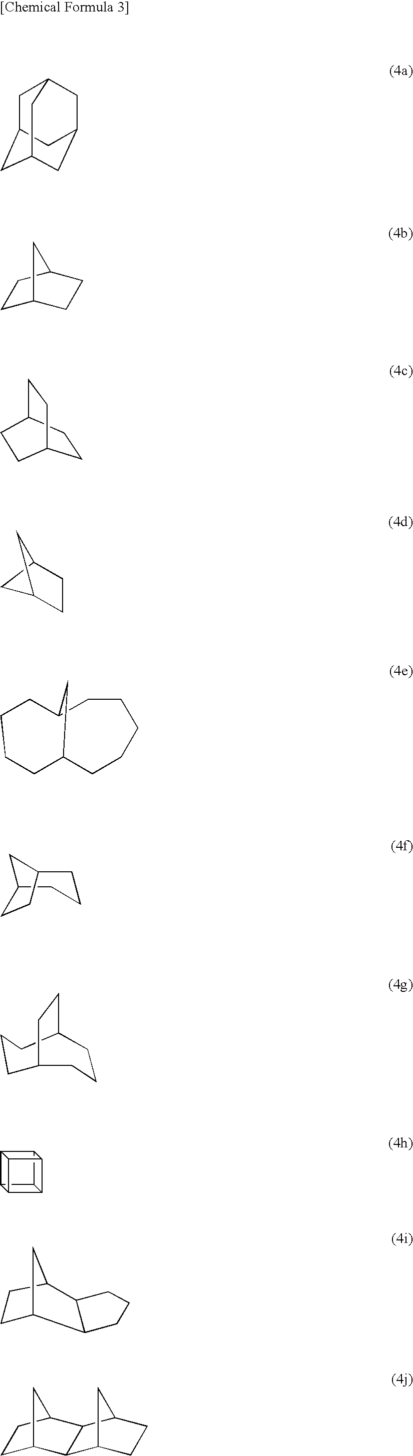

Of such aliphatic polyols, bridged alicyclic polyols are preferred, of which adamantanepolyols each having an adamantane ring (4a) and two or more hydroxyl groups bound at the tertiary positions of the adamantane ring are more preferred, for further higher etching resistance.

### (Aromatic Polyols)

The aromatic polyol is a compound having at least one aromatic ring and two or more hydroxyl groups bound to the aromatic ring and is represented by following Formula (5):

R′—(OH)ₙ₂ (5)

wherein R′ represents an aromatic hydrocarbon group; and n2 denotes an integer of 2 or more. When R′ has two or more aromatic rings, the two or more hydroxyl groups may be bound to the same aromatic ring or to different aromatic rings.

In Formula (5), examples of R′ include aromatic hydrocarbon groups and groups each having an aromatic hydrocarbon group to which a chain aliphatic hydrocarbon group and/or cycloaliphatic hydrocarbon group is bound. Exemplary aromatic hydrocarbon groups include aromatic hydrocarbon groups having about 6 to 14 carbon atoms, such as phenyl and naphthyl groups, of which those having about 6 to 10 carbon atoms are preferred. Examples of the chain aliphatic hydrocarbon group and of the cycloaliphatic hydrocarbon group are as with the exemplary chain aliphatic hydrocarbon groups and cycloaliphatic hydrocarbon groups as R.

Exemplary groups each having an aromatic hydrocarbon group to which a chain aliphatic hydrocarbon group is bound include alkyl-substituted aryl groups, such as phenyl group or naphthyl group on which about one to four alkyl groups having 1 to 4 carbon atoms are substituted.

The aromatic hydrocarbon group may have one or more substituents such as halogen atoms, oxo group, hydroxyl group, substituted oxy groups (e.g., alkoxy groups, aryloxy groups, aralkyloxy groups, and acyloxy groups), carboxyl group, substituted oxycarbonyl groups (e.g., alkoxycarbonyl groups, aryloxycarbonyl group, and aralkyloxycarbonyl groups), substituted or unsubstituted carbamoyl groups, cyano group, nitro group, substituted or unsubstituted amino groups, sulfo group, and heterocyclic groups. The hydroxyl group and carboxyl group-may be respectively protected by. protecting groups customarily used in organic syntheses. An aromatic or nonaromatic heterocyclic ring may be fused (condensed) to the ring of the aromatic hydrocarbon group.

Exemplary aromatic polyols include hydroquinone; resorcinol; naphthalenepolyols such as 1,3-dihydroxynaphthalene and 1,4-dihydroxynaphthalene; biphenols; bis(4-hydroxyphenyl)methane; bisphenol-A; and 1,1,1-(4-hydroxyphenyl)ethane. Among them, hydroquinone and naphthalenepolyols are easily available and are therefore advantageously used in the present invention.

Exemplary acid catalysts for use in the acid-catalyzed reaction include Lewis acids such as aluminum chloride, iron(III) chloride, tin(IV) chloride; and zinc(II) chloride; and protonic acids such as hydrogen fluoride (HF), sulfuric acid, p-toluenesulfonic acid, and phosphoric acid. Each of these can be used alone or in combination. Typically in the production of semiconductor devices, organic acids such as sulfuric acid and p-toluenesulfonic acid are preferably used as the acid catalysts, because the production should be performed while avoiding contamination of metal components. Such acid catalysts are used in an amount of, for example, about 0.01 to 10 moles and preferably about 0.1 to 5 moles, per 1 mole of the aliphatic polyol.

The acid-catalyzed reaction is performed in the presence of a solvent inert to the reaction, or in the absence of a solvent. Examples of the solvent include hydrocarbons such as hexane, cyclohexane, and toluene; halogenated hydrocarbons such as methylene chloride, 1,2-dichloroethane, chloroform, carbon tetrachloride, and chlorobenzene; chain or cyclic ethers such as diethyl ether, dimethoxyethane, tetrahydrofuran, and dioxane; nitriles such as acetonitrile and benzonitrile; esters such as ethyl acetate and n-butyl acetate; carboxylic acids such as acetic acid; amides such as N,N-dimethylformamide; ketones such as acetone and methyl ethyl ketone; nitro compounds such as nitromethane and nitrobenzene; and mixtures of them.

The reaction temperature in the acid-catalyzed reaction can be chosen as appropriate according typically to the types of reaction components. Typically, when 1,3,5-adamantanetriol and hydroquinone are used as the aliphatic polyol and the aromatic polyol, respectively, the reaction is performed at a temperature of typically around room temperature (25° C.) to 200° C. and preferably around 50° C. to 150° C. The reaction can be performed according to any system such as batch system, semi-batch system, or continuous system.

The aromatic polyol is used in an amount of generally about 1.0 to 100 moles, preferably about 3.0 to 50 moles, and more preferably about 5.0 to 20 moles, per 1 mole of the aliphatic polyol. The aromatic polyol may be used in large excess.

The reaction gives a corresponding polyol compound. After the completion of the reaction, the reaction product can be separated and purified according to a common separation/purification procedure such as adjustment of acidity or alkalinity, filtration, concentration, crystallization, washing, recrystallization, and/or column chromatography. A solvent for crystallization (crystallization solvent) can be any solvent in which the produced polyol compound is insoluble, and examples thereof include hydrocarbons such as hexane, heptane, and cyclohexane. In a preferred embodiment of the present invention, a solvent mixture is used as the crystallization solvent, which solvent mixture contains both a solvent in which the produced polyol compound is insoluble and another solvent in which the material aliphatic polyol and aromatic polyol are soluble. This is because the use of the solvent mixture helps to remove the residual material aliphatic polyol and aromatic polyol more easily, resulting in higher purification efficiency. Examples of the solvent in which the material aliphatic polyol and aromatic polyol are soluble include ethers such as tetrahydrofuran; ketones such as acetone and 2-butanone; esters such as ethyl acetate; and alcohols such as methanol and ethanol. The mixing ratio of respective solvents in the solvent mixture can be adjusted as appropriate. As used herein the term “crystallization” (deposition) also means and includes precipitation or settlement.

The reaction product often contains components insoluble in an alkaline developer. Examples of such components include (i) components having relatively high molecular weights of more than 2000; and (ii) compounds, even having molecular weights of 1000 to 2000, containing phenolic hydroxyl groups of the polyol compound which have been sealed or blocked typically through transesterification with the solvent during the reaction. If a polyol compound containing components insoluble in an alkaline developer is used for resist, the insoluble components may adversely affect the roughness in patterning and/or may cause particles during development, and the particles may remain as foreign substances in the formed pattern. To avoid these, it is preferred to provide the step of mixing a solution of the polyol compound in a solvent with a poor solvent with respect to a compound having one or more phenolic hydroxyl groups to deposit or separate as a different layer (to separate as a liquid) hydrophobic impurities to thereby remove the hydrophobic impurities. This step, when provided, helps to remove the components efficiently and to produce a high-purity polyol compound efficiently, and the resulting polyol compound is useful for the preparation of a resist composition which gives a resist pattern with less LER while exhibiting excellent resolution and high etching resistance.

Exemplary solvents for the formation of a solution of the polyol compound include ethers such as tetrahydrofuran; ketones such as acetone and 2-butanone; esters such as ethyl acetate and n-butyl acetate; and alcohols such as methanol and ethanol. Each of these solvents can be used alone or in combination. The solution of the polyol compound to be subjected to the removal operation of hydrophobic impurities can be either a reaction solution (reaction mixture) obtained as a result of the acid-catalyzed reaction, or a solution obtained by subjecting the reaction solution to an operation such as dilution, concentration, filtration, adjustment of acidity or alkalinity, and/or solvent exchange.

The solution of the polyol compound to be subjected to the removal operation of hydrophobic impurities has a content of the polyol compound of typically 1 to 40 percent by weight and preferably 3 to 30 percent by weight.

Examples of the poor solvent with respect to a compound having one or more phenolic hydroxyl groups include solvents having a solubility (25° C.) of phenol of 1 g/100 g or less. Specific examples of the poor solvent with respect to a compound having one or more phenolic hydroxyl groups include hydrocarbons including aliphatic hydrocarbons such as hexane and heptane, and alicyclic hydrocarbons Such as cyclohexane; solvent mixtures each containing water and one or more water-miscible organic solvents (e.g., alcohols such as methanol and ethanol; ketones such as acetone; nitriles such as acetonitrile; and cyclic ethers such as tetrahydrofuran); and water. Each of these solvents can be used alone or in combination. The poor solvent is used in an amount of typically 1 to 55 parts by weight and preferably 5 to 50 parts by weight, per 100 parts by weight of the solution containing the polyol compound.

Upon mixing of the solution of the polyol compound and the poor solvent, it is acceptable to add the poor solvent to the solution of the polyol compound or to add the solution of the polyol compound to the poor solvent; but it is more preferred to add the poor solvent gradually to the solution of the polyol compound.

The deposited or layer-separated hydrophobic impurities can be removed according to a procedure such as filtration, centrifugal separation, or decantation. The solution after the removal of the hydrophobic impurities is further mixed with another portion of the poor solvent with respect to a compound having one or more phenolic hydroxyl groups to thereby allow the polyol compound to deposit or to be separated as a different layer. In this procedure, it is acceptable to add the poor solvent to the solution after the removal of the hydrophobic impurities or to add the solution after the removal of the hydrophobic impurities to the poor solvent; but it is more preferred to add the solution after the removal of the hydrophobic impurities to the poor solvent. The amount of the poor solvent in this step is typically 60 to 1000 parts by weight and preferably 65 to 800 parts by weight, per 100 parts by weight of the solution after the removal of the hydrophobic impurities (solution containing the polyol compound).

The deposited or layer-separated polyol compound can be recovered typically through filtration, centrifugal separation, and/or decantation. The poor solvent for use in the deposition or layer-separation of hydrophobic impurities may be the same as or different from the poor solvent for use in the deposition or layer-separation of the target polyol compound. Where necessary, the obtained polyol compound is subjected to drying.

Exemplary alkali-soluble polymer compounds for use in the present invention include polyol compounds represented by following Formulae (6a), (6b), and (6c), wherein “s”, “t”, and “u” may be the same as or different from one another and each denote an integer of 0 or more; and the symbol “. . . ” indicates that a repeating unit of “adamantine ring-hydroquinone” may be further repeated or terminated here.

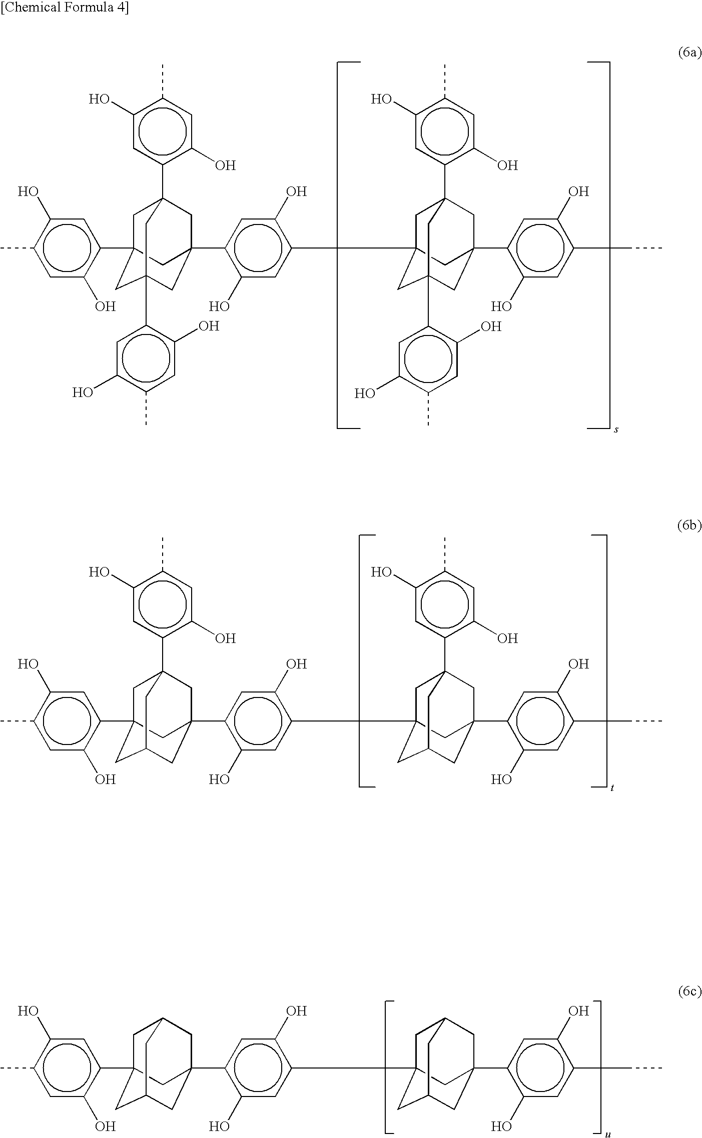

The alkali-soluble polymer compound has a weight-average molecular weight of about 500 to 5000, preferably about 1000 to 3000, and more preferably about 1000 to 2000. The alkali-soluble polymer compound, if having a weight-average molecular weight of more than 5000, may have an excessively large particle diameter and may tend to insufficiently help to reduce LER. In contrast, the alkali-soluble polymer compound, if having a weight-average molecular weight of less than 500, may tend to cause insufficient thermal stability. The alkali-soluble polymer compound has a molecular weight distribution (Mw/Mn) of typically about 1.0 to 2.5. The symbol Mn indicates a number-average molecular weight, and both Mn and Mw are values in terms of a standard polystyrene.

The polymer compounds for photoresists according to the present invention are polymer compounds which contain alkali-soluble groups being protected by protecting groups capable of leaving with an acid, which are sparingly soluble or insoluble in an alkaline developer, and which have structures where two or more molecules of an alkali-soluble polymer compound are bound to each other through the protecting group. In the absence of the action of an acid, the polymer compounds have large molecular weights, are thereby resistant to crystallization, have such properties as to give excellent workability, and can give resist patterns with less pattern collapse. They excel in etching resistance and, by controlling the protecting ratio by the protecting groups or by adjusting the structures of the protecting groups, they can give an excellent adhesion properties to a base (substrate).

The polymer compounds for photoresists according to the present invention can exhibit high solubility in an alkaline developer by allowing an acid to act to thereby allow the protecting groups to leave easily. The polymer compounds can form high-resolution resist patterns with less LER, because the binding between molecules of the alkali-soluble polymer compound can be easily dissociated by the action of the acid to allow the protecting groups to leave. The polymer compounds for photoresists according to the present invention are therefore usable as highly functional polymers in a variety of fields.

[Photoresist Compositions]

Photoresist compositions according to the present invention each contain at least any of the polymer compounds for photoresists according to the present invention. The photoresist compositions each preferably further contain other components such as a light-activatable acid generator (photo-acid-generating agent) and a resist solvent.

Exemplary light-activatable acid generators usable in the present invention include common or known compounds that efficiently generate an acid through exposure, including diazonium salts, iodonium salts (e.g., diphenyliodo hexafluorophosphate), sulfonium salts (e.g., triphenylsulfonium hexafluoroantimonate, triphenylsulfonium hexafluorophosphate, triphenylsulfonium methanesulfonate, and triphenylsulfonium trifluoromethanesulfonate), sulfonic acid esters [e.g., 1-phenyl-1-(4-methylphenyl)sulfonyloxy-1-benzoylmethane, 1,2,3-trisulfonyloxymethylbenzene, 1,3-dinitro-2-(4-phenylsulfonyloxymethyl)benzene, and 1-phenyl-1-(4-methylphenylsulfonyloxymethyl)-1-hydroxy-1-benzoylmethane], oxathiazole derivatives, s-triazine derivatives, disulfone derivatives (e.g., diphenyldisulfone), imide compounds, oxime sulfonates, diazonaphthoquinone, and benzoin tosylate. Each of these light-activatable acid generators can be used alone or in combination.

The amount of the light-activatable acid generators can be chosen as appropriate according typically to the strength of the acid generated upon irradiation with light and the proportion of the polymer compound concentration, within ranges of typically about 0.1 to 30 parts by weight, preferably about 1 to 25 parts by weight, and more preferably about 2 to 20 parts by weight, per 100 parts by weight of the polymer compound concentration.

Examples of the resist solvent include glycol solvents, ester solvents, ketone solvents, and mixtures of these solvents. Among them, preferred are propylene glycol monomethyl ether, propylene glycol monomethyl ether acetate, ethyl lactate, methyl isobutyl ketone, methyl amyl ketone, and mixtures of them; of which more preferred are solvents each containing at least propylene glycol monomethyl ether acetate. Examples thereof include a single solvent of propylene glycol monomethyl ether acetate alone; a solvent mixture containing both propylene glycol monomethyl ether acetate and propylene glycol monomethyl ether; and a solvent mixture containing both propylene glycol monomethyl ether acetate and ethyl lactate.

The concentration of the polymer compound for photoresists in the photoresist compositions can be set as appropriate according to the thickness of the coated film (resist film) within such a range that the photoresist composition can be applied (coated) to a substrate or base and is typically about 2 to 20 percent by weight and preferably about 5 to 15 percent by weight. The photoresist compositions may further contain other components including alkali-soluble components such as alkali-soluble resins (e.g., novolak resins, phenol resins, imide resins, and carboxyl-group containing resins); and colorants (e.g., dyestuffs). The photoresist compositions may further contain any of the alkali-soluble polymer compounds for use in the present invention, which is not protected by a group capable of leaving with an acid.

[Process for Formation of Resist Pattern]

A process for the formation of a resist pattern according to the present invention includes the steps of forming a resist film from any of the photoresist compositions according to the present invention; pattern-wise exposing the resist film; and developing the pattern-wise-exposed resist film.

The photoresist composition is applied to a base or substrate to give a film, and the film is dried to give the resist film. The resist film is then irradiated with light (exposed to light) through a predetermined mask to form a latent-image pattern and is then developed to form a fine pattern with a high accuracy.

Exemplary materials for the base or substrate include silicon wafers, metals, plastics, glass, and ceramics. The application of the photoresist composition can be performed using a customary coating device such as spin coater, dip coater, or roller coater. The resist film has a thickness of typically about 0.01 to 10 μm and preferably about 0.03 to 1 μm.

For the exposure, any of light rays of different wavelengths, such as ultraviolet rays and X-rays, can be used. Typically, g line, i line, excimer laser (e.g., XeCl, KrF, KrCl, ArF, or ArCl laser), and EUV (extreme ultraviolet) are generally used for semiconductor resist use. The exposure is performed at an exposure energy of typically about 1 to 1000 mJ/cm² and preferably about 10 to 500 mJ/cm².

The exposure causes the light-activatable acid generator to generate an acid. Next, a post-exposure baking (hereinafter also referred to as “PEB treatment”) is performed to allow the generated acid to act on the protecting groups of the polymer compound for photoresists to leave rapidly from the polymer compound to give phenolic hydroxyl groups which help the polymer compound to be soluble in an alkaline developer. The development with the alkaline developer therefore gives a predetermined pattern with a high accuracy. The PEB treatment may be performed typically under conditions at a temperature of about 50° C. to 180° C. for a duration of about 0.1 to 10 minutes and preferably about 1 to 3 minutes.

The post-exposure-based resist film is subjected to development with a developer to remove exposed portions. Thus, the resist film is patterned. The development is performed according to a procedure such as dispensing development (puddle development), dipping development, and vibration/dipping development. An alkaline aqueous solution (e.g., a 0.1 to 10 percent by weight aqueous tetramethylammonium hydroxide solution) can be used as the developer.

### EXAMPLES

The present invention will be illustrated in further detail with reference to several working examples below. It should be noted, however, that these examples are never construed to limit the scope of the present invention.

Under the following conditions, ¹H-NMR analyses and GPC measurements were performed.

Conditions for ¹H-NMR analyses
Main unit: 500-MHz NMR analyzer supplied by JEOL Ltd.
Sample concentration: 3% (wt/wt)
Solvent: Deuterated dimethyl sulfoxide (deuterated DMSO)
Internal standard: Tetramethylsilane (TMS)

Conditions for GPC (Gel Permeation Chromatography)
Measurements
Column: Three TSKgel SuperHZM-M columns
Column temperature: 40° C.
Eluent: Tetrahydrofuran
Flow rate of eluent: 0.6 mL/min.
Sample concentration: 20 mg/mL
Injection volume: 10 μL

### Preparation Example 1

In a 200-mL three-necked flask equipped with a Dimroth condenser, a thermometer, and a stirring bar were placed 2.18 g of 1,3,5-adamantanetriol, 7.82 g of hydroquinone, 13.51 g of p-toluenesulfonic acid, and 56.67 g of n-butyl acetate, followed by stirring thoroughly. Next, the flask was purged with nitrogen and submerged in an oil bath heated to 140° C., to start heating with stirring. After being kept heating under reflux for 2 hours, the flask was cooled.

The cooled reaction solution was transferred from the flask to a separatory funnel, washed with 80 g of distilled water, and further washed with five portions of 65 g of distilled water. The washed reaction solution had a weight of 55.4 g. The washed reaction solution was poured into 500 g of n-heptane, to deposit orange fine particles. The fine particles were collected through filtration, dried at 60° C. for 12 hours, and thereby yielded 5.8 g of an alkali-soluble polymer compound 1. The prepared alkali-soluble polymer compound 1 was subjected to a GPC measurement and found to have a weight-average molecular weight in terms of standard polystyrene of 1100 and a molecular weight distribution of 1.69. Independently, the alkali-soluble polymer compound 1 was subjected to a ¹H-NMR measurement in dimethyl sulfoxide-d6 and found to show peaks from protons of phenolic hydroxyl groups at around 8 to 9 ppm, peaks from aromatic protons at around 6 to 7 ppm, and peaks from protons of adamantane ring at around 1 to 3 ppm.

### Preparation Example 2

In a 200-mL three-necked flask equipped with a Dimroth condenser, a thermometer, and a stirring bar were placed 5.85 g of 1,3,5-adamantanetriol, 24.18 g of hydroquinone, 15.04 g of p-toluenesulfonic acid, and 170.02 g of n-butyl acetate, followed by stirring thoroughly. Next, the flask was purged with nitrogen and submerged in an oil bath heated to 140° C., to start heating with stirring. After being kept heating under reflux for one hour, the flask was cooled.

The cooled reaction solution was transferred from the flask to a separatory funnel, washed with 100 g of distilled water, and further washed with five portions of 100 g of distilled water. The washed reaction solution had a weight of 181.4 g. An aliquot (116.6 g) of n-heptane was poured into the washed reaction solution to cause an orange liquid to be separated as a different layer and to settle. The settled layer was removed using a separatory funnel, and the upper layer was further added to 207.9 g of heptane to cause a slightly yellow liquid to settle. This liquid was separated, dried at 45° C. for 8 hours, and thereby yielded 16.5 g of an alkali-soluble polymer compound 2. The prepared alkali-soluble polymer compound 2 was subjected to a GPC measurement and found to have a weight-average molecular weight in terms of standard polystyrene of 1000 and a molecular weight distribution of 1.13.

### Example 1

In a 20-mL glass ampule were placed 0.2 g of the alkali-soluble polymer compound 1 prepared in Preparation Example 1, 0.003 g of p-toluenesulfonic acid, and 1.0 g of n-butyl acetate to give a homogeneous solution. The ampule was purged with nitrogen and cooled with ice. Independently, 0.4 g of vinyloxymethylcyclohexane, 0.1 g of 1,4-di(vinyloxymethyl)cyclohexane, and 1.0 g of n-butyl acetate were placed in a glass bottle to give a homogeneous solution. The glass bottle was purged with nitrogen, the contents of which were added to the contents in the glass ampule, followed by stirring for 30 minutes with ice-cooling. The mixture was then further stirred at room temperature (25° C.) for 2 hours. Thereafter 30 g of methanol was poured thereinto to deposit solids, the solids were collected through filtration, dried at 30° C. for 12 hours, and thereby yielded 0.40.g of a polymer'compound 1 for photoresists.

The prepared polymer compound 1 for photoresists was subjected to a GPC measurement and found to have a weight-average molecular weight in terms of standard polystyrene of 7300 and a molecular weight distribution of 3.75. Independently, the polymer compound 1 for photoresists was subjected to a ¹H-NMR measurement in dimethyl sulfoxide-d6 to find that the peaks from protons of phenolic hydroxyl groups, which had been observed at around 8 to 9 ppm, disappeared, demonstrating that phenolic hydroxyl groups were protected by protecting groups.

### Example 2

The procedure of Example 1 was performed, except for using 1,3-divinyloxyadamantane instead of 1,4-di(vinyloxymethyl)cyclohexane, to yield 0.35 g of a polymer compound 2 for photoresists.

The prepared polymer compound 2 for photoresists was subjected to a GPC measurement and found to have a weight average molecular weight in terms of standard polystyrene of 8500 and a molecular weight distribution of 3.85. Independently, the polymer compound 2 for photoresists was subjected to a ¹H-NMR measurement in dimethyl sulfoxide-d6 to find that the peaks from protons of phenolic hydroxyl groups, which had been observed at around 8 to 9 ppm, disappeared, demonstrating that phenolic hydroxyl groups were protected by protecting groups.

### Example 3

The procedure of Example 1 was performed, except for using 2,6-dioxa-4,8-divinyloxybicyclo[3.3.0]octane instead of 1,4-di(vinyloxymethyl)cyclohexane, to yield 0.32 g of a polymer compound 3 for photoresists.

The prepared polymer compound 3 for photoresists was subjected to a GPC measurement and found to have a weight-average molecular weight in terms of standard polystyrene of 8050 and a molecular weight distribution of 3.55. Independently, the polymer compound 3 for photoresists was subjected to a ¹H-NMR measurement in dimethyl sulfoxide-d6 to find that the peaks from protons of phenolic hydroxyl groups, which had been observed at around 8 to 9 ppm, disappeared, demonstrating that phenolic hydroxyl groups were protected by protecting groups.

### Example 4

In a 100-mL eggplant flask were placed 0.3 g of the polyol compound 2 for photoresists prepared in Preparation Example 2, 0.003 g of p-toluenesulfonic acid, and 12.0 g of n-butyl acetate to give a homogeneous solution, and the flask was purged with nitrogen. Independently, 0.48 g of cyclohexane vinyl ether, 0.06 g of cyclohexanedimethanol divinyl ether, and 3.0 g of n-butyl acetate were placed in a glass bottle to give a homogeneous solution, the glass bottle was purged with nitrogen, the contents of which were added to the contents in the eggplant flask, followed by stirring at room temperature (25° C.) for one hour. The mixture was then poured into 100 g of a 3:1 (by weight) mixture of methanol and water to deposit solids, the deposited solids were collected through filtration, dried at 30° C. for 12 hours, and thereby yielded 0.35 g of a polymer compound 4 for photoresists.

The prepared polymer compound 4 for photoresists was subjected to a GPC measurement and found to have a weight-average molecular weight in terms of standard polystyrene of 1620 and a molecular weight distribution of 1.24. The compound 4 for photoresists was subjected to a ¹H-NMR measurement in dimethyl sulfoxide-d6 to find that the peaks from protons of phenolic hydroxyl groups, which had been observed at around 8 to 9 ppm, disappeared, demonstrating that phenolic hydroxyl groups were protected by protecting groups.

### Example 5

The procedure of Example 4 was performed, except for using cyclohexane vinyl ether in an amount of 0.41 g and using cyclohexanedimethanol divinyl ether in an amount of 0.13 g, to yield 0.41 g of a polymer compound 5 for photoresists.

The prepared polymer compound 5 for photoresists was subjected to a GPC measurement and found to have a weight-average molecular weight in terms of standard polystyrene of 4940 and a molecular weight distribution of 2.61. Independently, the polymer compound 5 for photoresists was subjected to a ¹H-NMR measurement in dimethyl sulfoxide-d6 to find that the peaks from protons of phenolic hydroxyl groups, which had been observed at around 8 to 9 ppm, disappeared, demonstrating that phenolic hydroxyl groups were protected by protecting groups.

Evaluation Tests

The polymer compounds 1 to 3 for photoresists obtained in Examples 1 to 3 were evaluated respectively according to the following method.

Specifically, 100 parts by weight of a sample polymer compound for photoresists, 5 parts by weight of triphenylsulfonium trifluoromethanesulfonate, and an appropriate amount of propylene glycol monomethyl ether acetate were mixed to give a photoresist composition having a concentration of the polymer compound for photoresists of 15 percent by weight.

The prepared photoresist composition was applied to a silicon wafer through spin coating so as to form a resist film 500 nm thick and prebaked on a hot plate at a temperature of 100° C. for 120 seconds. The resist film was exposed to KrF-excimer laser beams at an irradiance level of 30 mJ/cm², and subjected to a PEB treatment at a temperature of 100° C. for 60 seconds. Next, the resist film was developed with a 2.38% aqueous tetramethylammonium hydroxide solution for 60 seconds and rinsed with pure water. As a result, all the samples gave 0.20 μm-wide line-and-space patterns.

### INDUSTRIAL APPLICABILITY

In the absence of the action of an acid, the polymer compounds for photoresists according to the present invention have large molecular weights, are thereby resistant to crystallization, excel in workability, and give resist patterns with less pattern collapse. In contrast, in the presence of the action of an acid, the protecting group leaves to dissociate the binding between the molecules of the alkali-soluble polymer compound, and the polymer compounds for photoresists can thereby give resist patterns with less LER. For example, even in photolithography using extreme ultraviolet (EUV; having a wavelength of about 13.5 nm) so as to give a line-and-space pattern of about 22 nm, the polymer compounds for photoresists can give high-resolution resist patterns with a reduced LER of 2 nm or less.

1. A polymer compound for photoresists, the polymer compound comprising alkali-soluble groups being protected by protecting groups capable of leaving with an acid, and the polymer compound being insoluble or sparingly soluble in an alkaline developer, wherein part or all of the protecting groups are multifunctional protecting groups each protecting two or more alkali-soluble groups.

2. The polymer compound for photoresists according to claim 1, wherein the alkali-soluble groups are phenolic hydroxyl groups.

3. The polymer compound for photoresists according to claim 1 or 2, the polymer compound for photoresists being a polyol compound having at least one aliphatic group and at least one aromatic group bound to each other alternately, the aromatic group having at least one aromatic ring and two or more phenolic hydroxyl groups bound to the aromatic ring, the phenolic hydroxyl groups in the polyol compound protected by protecting groups capable of leaving with an acid.

4. The polymer compound for photoresists according to claim 3, wherein the polyol compound is a product of an acid-catalyzed reaction between an aliphatic polyol and an aromatic polyol.

5. The polymer compound for photoresists according to claim 4, wherein the acid-catalyzed reaction is a FriedelCrafts reaction.

6. The polymer compound for photoresists according to claim 4, wherein the aliphatic polyol is an alicyclic polyol.

7. The polymer compound for photoresists according to claim, wherein the aliphatic polyol is an adamantanepolyol having an adamantane ring and two or more hydroxyl groups bound at the tertiary positions of the adamantane ring.

8. The polymer compound for photoresists according to claim 4, wherein the aromatic polyol is hydroquinone.

9. The polymer compound for photoresists according to claim 4, wherein the aromatic polyol is a naphthalenepolyol.

10. The polymer compound for photoresists according to claim 1, wherein the polymer compound for photoresists before the protection of the alkali-soluble groups by the protecting groups capable of leaving with an acid has a weight-average molecular weight of 500 to 5000.

11. The polymer compound for photoresists according to claim 1, wherein an acetal group is formed as a result of the protection of the alkali-soluble group by the protecting group capable of leaving with an acid.

12. The polymer compound for photoresists according to claim 11, wherein the acetal structure is formed through a reaction between a phenolic hydroxyl group and a vinyl ether compound.

13. A photoresist composition comprising at leas the polymer compound for photoresists according to claim 1.

14. A process for the formation of a resist pattern, the process comprising the steps of forming a resist film from the photoresist composition according to claim 13; patternwise exposing the resist film; and developing the pattern-wise-exposed resist film.
